(19) United States
(12) Patent Application Publication
(10) Pub. No.: US 2016/0234965 A1
(43) Pub. Date: Aug. 11, 2016

(54) COOLING MODULE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: HAI-YUN WANG, Wuhan (CN)

(21) Appl. No.: 14/695,605

(22) Filed: Apr. 24, 2015

(30) Foreign Application Priority Data
Feb. 10, 2015 (CN) 201510067807.1

(51) Int. Cl. H05K 7/20; G06F 1/20

(52) U.S. Cl. CPC H05K 7/20154; G06F 1/20

(57) ABSTRACT

A cooling module is configured to cool an electronic component installed in a chassis. The cooling module includes a radiator configured to absorb heat of the electronic component, a fan module, and a heat dissipating member. The heat dissipating member includes an absorption end fixed on the radiator and a radiating end covered on the fan module. The absorption end is configured to absorb the heat of the radiator and transfer to the radiating end. The fan module is configured to drive airflow through the heat dissipating member to dissipate the heat of the heat dissipating member to cool the electronic component.

### CROSS-REFERENCE TO RELATED APPLICATIONS

This application claims priority to Chinese Patent Application No. 201510067807.1 filed on Feb. 10, 2015 in the China Intellectual Property Office, the contents of which are incorporated by reference herein.

### FIELD

The disclosure generally relates to a cooling module.

### BACKGROUND

With the development of electronic science and technology, electronic devices work more quickly by using electronic components which consume high power. However, these high-power electronic components generate more heat when running In order to quickly dissipate the heat, radiators are installed to cool the electronic components.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a cooling module and a chassis.

FIG. 2 is similar to FIG. 1, but viewed from a different angle.

FIG. 3 is an isometric, partly assembled view of the cooling module and the chassis of FIG. 1.

FIG. 4 is an isometric, assembled view of the cooling module and the chassis of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

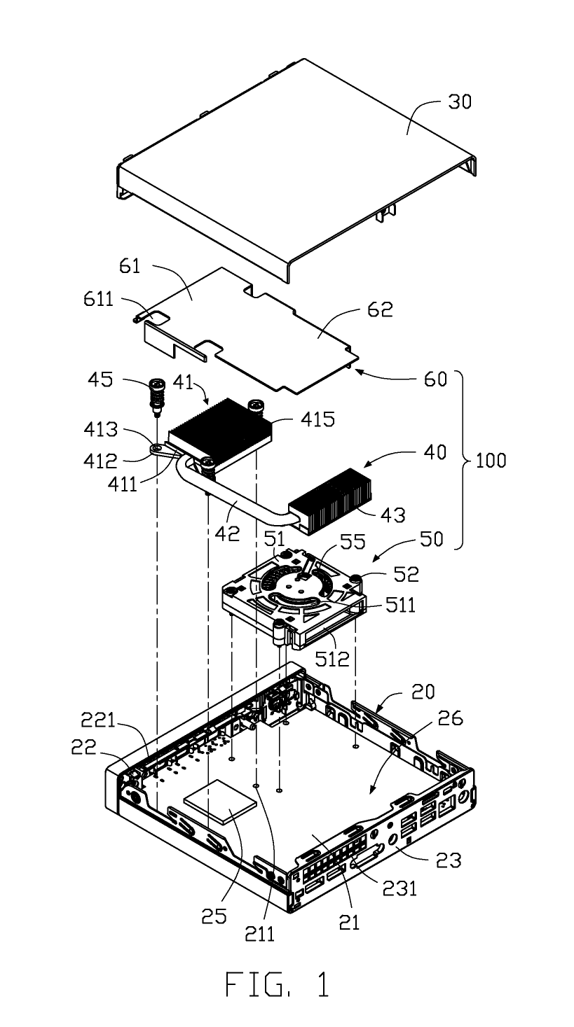

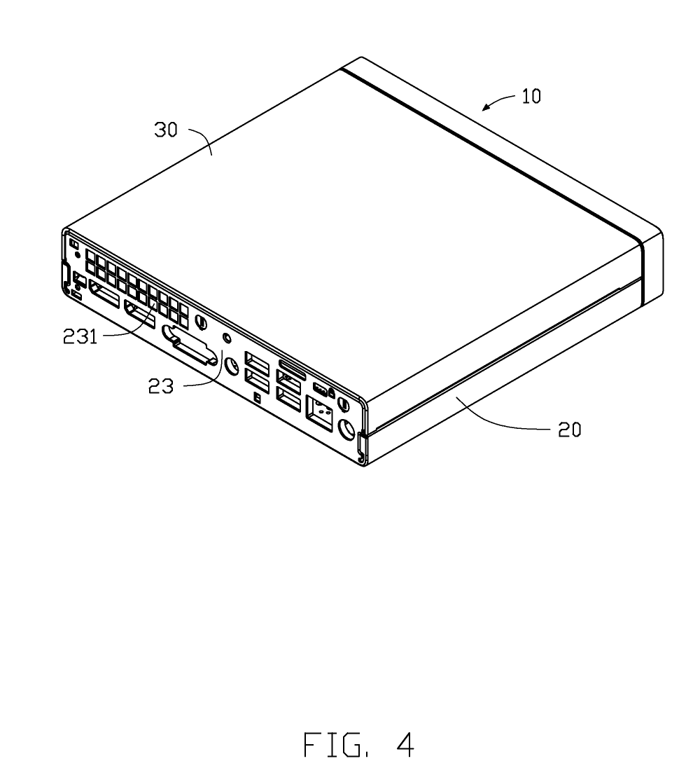

FIG. 1 illustrates one embodiment of a cooling module 100. The cooling module 100 is configured to cool an electronic component 25 installed in a chassis 10 (shown in FIG. 4). The cooling module 100 includes a radiator 40, a fan module 50 and a heat dissipating member 60 fixed on the radiator 40.

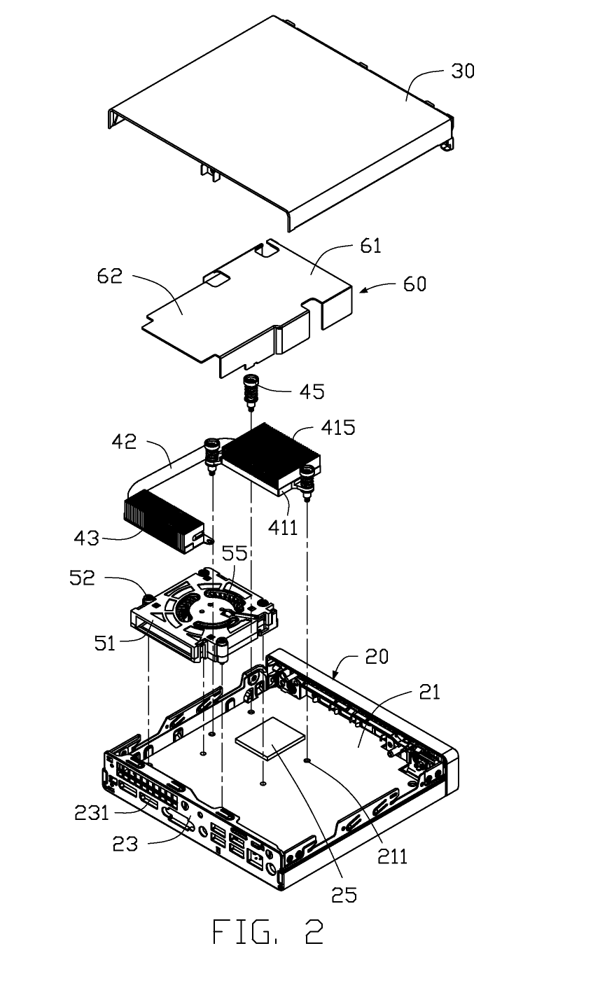

FIGS. 1 and 2 illustrate the chassis 10 includes a base 20 and a cover plate 30 fixed on the base 20. A motherboard 21 is located on the base 20. The electronic component 25 is fixed on the motherboard 21. The motherboard 21 defines a plurality of fixing holes 211 around the electronic component 25. The base 20 includes a front plate 22 and a rear plate 23 parallel to the front plate 22. The front plate 22 defines a plurality of air inlets 221. The rear plate 23 defines a plurality of air outlets 231. The cover plate 30 can be fixed on the base 20. The base 20 and the cover plate 30 cooperatively define a receiving space 26. In at least one embodiment, the electronic component 25 is a Central Processing Unit (CPU).

The radiator 40 includes an heat sink 41, a heat pipe 42 and a radiator portion 43. The heat sink 41 includes a base plate 411 and a plurality of fins 45 fixed on the base plate 411. Three fixing portions 412 are located around the base plate 411. The fixing portion 412 defines a through hole 413. One fixing piece 45 can pass through the through hole 413 and be inserted into the fixing hole 211 to fix the radiator 40 on the motherboard 21. The fins 415 are parallel to each other and are substantially perpendicular to the base plate 411.

One end of the heat pipe 42 is received in the heat sink 41 and another end of the heat pipe 42 is received in the radiator portion 43. The heat pipe 42 receives coolant (not shown). The coolant can absorb heat of the heat sink 41 and transfer heat to the radiator portion 43. The radiator portion 43 is fixed on the motherboard 21.

The fan module 50 includes a fixing bracket 51 and a cooling fan 55 received in the fixing bracket 51. A plurality of securing members 52 can pass through the fixing bracket 51 to fix the fan module 50 on the motherboard 21. The fixing bracket 51 defines a plurality of openings 511 and an air vent 512. The radiator portion 43 is aligned with the air vent 512. Airflow can enter into the fan module 50 through the opening 511 and exit the fan module 50 via the air vent 512.

The heat dissipating member 60 includes an absorption end 61 and a radiating end 62. The absorption end 61 can be fixed on the heat sink 41. The absorption end 61 defines three notches 611. The radiating end 62 is covering the fan module 50 and is aligned with the opening 511. A gap is formed between the radiating end 62 and the opening 511 which is configured to let the airflow pass through. The absorption end 61 is near to the heat sink 41 to absorb heat of the heat sink 41 and transfer the heat to the radiating end 62.

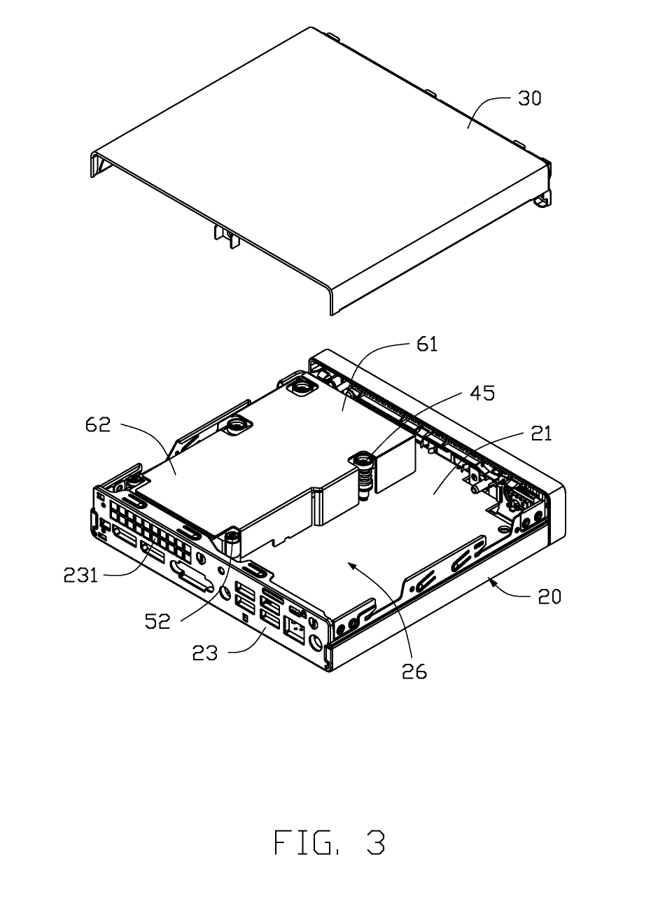

FIGS. 3 and 4 illustrate when in assembly, the radiator 40 is placed in the receiving space 26 and is supported on the motherboard 21. The base plate 411 is near to the electronic component 25. The through hole 413 is aligned with the fixing hole 211. The fixing piece 45 passes through the through hole 413 and is inserted into the fixing hole 211 to fix the radiator 40 on the motherboard 21. The fan module 50 is placed in the receiving space 26. The air vent 512 is aligned with the radiator portion 43. The securing member 52 passes through the fixing bracket 51 to fix the fan module 50 on the motherboard 21. The heat dissipating member 60 is placed on the radiator 40. The absorption end 61 is fixed on the heat sink 41. The radiating end 62 is covered on the opening 511. Then, the cooling module 100 is completely assembled. The cover plate 30 is fixed on the base 20 and the chassis 10 is completely assembled.

When the electronic component 25 is working, the base plate 411 absorbs the heat of the electronic component 25 and transfers the heat to the fins 415. Some of heat of the fins 415 is transferred to the heat pipe 42 and some of heat of the fins 415 is transferred to the absorption end 61. The coolant within the heat pipe 42 absorbs heat and transfers heat to the radiator portion 43. The absorption end 61 transfers heat to the radiating end 62. Airflow enters into the chassis through the air inlets 221, and enters into the fan module 50 after passing through the radiating end 62. Then, the airflow passes through the air vents 512 and the radiator portion 43 under the drive of cooling fan 55. Finally, the airflow leaves the chassis 10 from the air outlets 231 to dissipate heat from the electronic component 25.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A cooling module comprising:
a radiator configured to absorb heat of an electronic component installed in a chassis; and
a heat dissipating member comprising an absorption end fixed on the radiator and a radiating end covering a fan module configured to cool the radiating end;
wherein the absorption end is configured to absorb the heat and transfer to the radiating end.

2. The cooling module of claim 1, wherein the chassis comprises a base and a cover plate, the base and the cover plate cooperatively define a receiving space, and the cooling module is received in the receiving space.

3. The cooling module of claim 2, wherein a motherboard is located on the base, the electronic component is located on the motherboard.

4. The cooling module of claim 3, wherein the motherboard defines a plurality of fixing holes around the electronic component, a plurality of the fixing pieces can be inserted into the fixing holes to fix the cooling module on the motherboard.

5. The cooling module of claim 4, wherein the radiator comprises an heat sink, the heat sink comprises a base plate, the base plate is located closely the electronic component to absorb heat of the electronic component.

6. The cooling module of claim 5, wherein a plurality of fixing portion is located around the base plate, each of the plurality of the fixing portions defines a through hole, the plurality of fixing pieces are configured to pass through the through holes of the plurality of fixing portions and be inserted into the plurality of fixing holes to fix the cooling module on the motherboard.

7. The cooling module of claim 5, wherein the heat sink comprises a plurality of parallel fins perpendicularly fixed on the base plate, and the plurality of parallel fins absorb the heat of the base plate.

8. The cooling module of claim 5, wherein the radiator comprises a radiator portion and a heat pipe, the heat pipe transfers the heat of the heat sink to the radiator portion.

9. The cooling module of claim 1, wherein the fan module comprises a fixing bracket and a cooling fan received in the fixing bracket, the fixing bracket defines a plurality of opening and an air vent, the fan drivers airflow to enter into the fan module through the opening and go out of the fan module through the air vent.

10. The cooling module of claim 1, wherein the base defines an air inlet and an air outlet, the fan drivers airflow enter into the chassis through the air inlet and go out of the chassis through the air outlet to dissipate the heat of the electronic component.

11. An electronic device comprising:
a chassis receiving an electronic component;
a radiator configured to absorb heat of the electronic component;
a fan module; and
a heat dissipating member comprising an absorption end fixed on the radiator and a radiating end covered on the fan module;
wherein the absorption end is configured to absorb the heat and transfer to the radiating end, and the fan module is configured to cool the radiating end.

12. The electronic device of claim 11, wherein the chassis comprises a base and a cover plate, the base and the cover plate cooperatively define a receiving space, and the cooling module is received in the receiving space.

13. The electronic device of claim 12, wherein a motherboard is located on the base, the electronic component is located on the motherboard.

14. The electronic device of claim 13, wherein the motherboard defines a plurality of fixing holes around the electronic component, a plurality of the fixing pieces can be inserted into the fixing holes to fix the cooling module on the motherboard.

15. The electronic device of claim 14, wherein the radiator comprises an heat sink, the heat sink comprises a base plate, the base plate is located closely the electronic component to absorb heat of the electronic component.

16. The electronic device of claim 15, wherein a plurality of fixing portions are located around the base plate, each of the plurality of the fixing portions defines a through hole, the plurality of fixing pieces are configured to pass through the through holes of the plurality of fixing portions and be inserted into the plurality of fixing holes to fix the cooling module on the motherboard.

17. The electronic device of claim 15, wherein the heat sink comprises a plurality of parallel fins perpendicularly fixed on the base plate, and the plurality of parallel fins absorb the heat of the base plate.

18. The electronic device of claim 15, wherein the radiator comprises a radiator portion and a heat pipe, the heat pipe transfers the heat of the heat sink to the radiator portion.

19. The electronic device of claim 11, wherein the fan module comprises a fixing bracket and a cooling fan received in the fixing bracket, the fixing bracket defines a plurality of opening and an air vent, the fan drivers airflow enter into the fan module through the opening and go out of the fan module through the air vent.

20. The electronic device of claim 11, wherein the base defines an air inlet and an air outlet, the fan drivers airflow enter into the chassis through the air inlet and go out of the chassis through the air outlet to dissipate the heat of the electronic component.
